(19) United States
(12) Patent Application Publication
(10) Pub. No.: US 2024/0421104 A1
(43) Pub. Date: Dec. 19, 2024

(54) SELECTIVE WET CHANNELS FOR WATER DRAINAGE PPLICATIONS

(71) Applicants: SAUDI ARABIAN OIL COMPANY, Dhahran (SA); King Abdullah University of Science and Technology, Thuwal-Jeddah (SA)

(72) Inventors: Dong Kyu Cha, Dhahran (SA); Abdullah Abdulaziz AlOmier, Thuwal (SA); Subhash C. Ayirala, Dhahran (SA); Mohammed Badri Al-Otaibi, Dhahran (SA); Ali Abdallah Al-Yousef, Dhahran (SA); Hussein Hoteit, Thuwal (SA)

(73) Assignees: SAUDI ARABIANOIL COMPANY, Dhahran (SA); King Abdullah University of Science and Technology, Thuwal-Jeddah (SA)

(21) Appl. No.: 18/335,642

(22) Filed: Jun. 15, 2023

(51) Int. Cl. H01L 23/00; H01L 21/3065; H01L 21/56; H01L 23/29; H01L 23/31; H05K 1/02; H05K 3/22

(52) U.S. Cl. CPC H01L 23/564; H01L 21/3065; H01L 21/56; H01L 23/293; H01L 23/3171; H05K 1/0272; H05K 3/22; H01L 21/3085; H05K 2203/1173

(57) ABSTRACT

A method for water drainage of a substrate includes creating, on a surface of the substrate, a designated hydrophobic region having hydrophobic surfaces of a hydrophobic film. Electronic circuitries are fabricated in the designated hydrophobic region of the substrate. The method further includes creating, on the surface of the substrate, a designated hydrophilic region having hydrophilic surfaces of the substrate. A drainage channel is formed in the designated hydrophilic region. The method further includes facilitating, based on capillary imbibition of the drainage channel, fluid flow from the designated hydrophobic region to a drainage/evaporation port to prevent damage of the electronic circuitries by moisture accumulation in the designated hydrophobic region.

### BACKGROUND

Development of electronics is increasing rapidly driven by accelerated technological revolution, innovation, and commercialization of new products. Increased demand has also brought the attention about efficiency, quality, and durability of electronics manufacturing. Electronic parts are intensively used in vast range of applications which still capitalize on their competent efficiency and life-span. A common application is motherboard, defined as circuit board or logic board, which is the biggest component for a computer system that controls links between all components. It usually contains different components, such as read-only memory (ROM), central processing unit (CPU), random-access memory (RAM), peripheral component interconnect (PCI) slots, universal serial bus (USB) ports, etc.

Photolithography is a process used in microfabrication to pattern parts on a thin film or the bulk of a substrate, e.g., a semiconductor wafer. A photoresist is a light-sensitive material used in photolithography to form a patterned coating on a surface. A photoresist developer is a solvent to selectively remove the photoresist to form the patterned coating. As an example, photolithography may be applied in the process of exposing a pattern into photoresist, depositing a thin film over the entire area, then washing away the photoresist to leave behind the deposited thin film only in the patterned area. The step of washing away the photoresist along with the underlying portion of the thin film is referred to as “lift-off.”

### SUMMARY

In one aspect, embodiments of the present invention relate to a method for water drainage of a substrate. The method includes creating, on a surface of the substrate, a designated hydrophobic region having hydrophobic surfaces of a hydrophobic film, wherein electronic circuitries are fabricated in the designated hydrophobic region of the substrate, creating, on the surface of the substrate, a designated hydrophilic region having hydrophilic surfaces of the substrate, wherein a drainage channel is formed in the designated hydrophilic region, and facilitating, based on capillary imbibition of the drainage channel, fluid flow from the designated hydrophobic region to a drainage/evaporation port to prevent damage of the electronic circuitries by moisture accumulation in the designated hydrophobic region.

In one aspect, embodiments of the present invention relate to a substrate with improved water drainage. The substrate includes a designated hydrophobic region comprising hydrophobic surfaces of a hydrophobic film, wherein electronic circuitries are fabricated in the designated hydrophobic region of the substrate, and a designated hydrophilic region comprising hydrophilic surfaces of the substrate, wherein a drainage channel is formed in the designated hydrophilic region, wherein the drainage channel facilitates fluid flow from the designated hydrophobic region to a drainage/evaporation port of the silicon-based substrate to prevent damage of the electronic circuitries by moisture accumulation in the designated hydrophobic region.

In one aspect, embodiments of the present invention relate to a circuit module with improved water drainage. The circuit module includes a substrate comprising a designated hydrophobic region comprising hydrophobic surfaces of a hydrophobic film, and a designated hydrophilic region comprising hydrophilic surfaces of the substrate, wherein a drainage channel is formed in the designated hydrophilic region, a drainage/evaporation port of the substrate, and electronic circuitries fabricated in the designated hydrophobic region of the substrate, wherein the drainage channel facilitates fluid flow from the designated hydrophobic region to a drainage/evaporation port of the silicon-based substrate to prevent damage of the electronic circuitries by moisture accumulation in the designated hydrophobic region.

Other aspects and advantages of the invention will be apparent from the following description and the appended claims.

### BRIEF DESCRIPTION OF DRAWINGS

FIG. 1A shows an example of a motherboard or circuit board in an electronic device including a computer system in accordance with one or more embodiments.

FIG. 1B shows an example of a silicon-based circuit module in accordance with one or more embodiments.

FIG. 2A shows a flowchart of a method for fabricating a substrate with improved drainage in accordance with one or more embodiments.

FIG. 2B shows a flowchart of a method for fabricating a silicon-based substrate with improved drainage in accordance with one or more embodiments.

FIG. 3 shows a silicon-based substrate undergoing fabrication using a photolithographic process in accordance with one or more embodiments.

FIG. 4 shows an example test pattern of selective wettability control mask in accordance with one or more embodiments.

FIG. 5 shows an example of a wettability control mask with a test pattern in accordance with one or more embodiments.

FIG. 6 shows an example of a transferred test pattern from the wettability control mask onto a silicon wafer in accordance with one or more embodiments.

FIGS. 7 and 8 show examples of water droplet contact angles on the fabricated silicon-based substrate in accordance with one or more embodiments.

FIGS. 9A, 9B, and 9C show examples of fluid flow over alternating hydrophobic and hydrophilic regions of the fabricated silicon-based substrate in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skills in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Embodiments disclosed herein present a method to improve drainage of a substrate to protect electronic components fabricated on the substrate from damage due to contact with liquid. In one or more embodiments, the substrate includes a silicon-based substrate where surface wettability alteration technique is used to facilitate removal of trapped water and/or moisture from the silicon-based substrate embedded in electronics and integrated circuits. In one or more embodiments, hydrophobic surfaces and hydrophilic channels are formed in selected regions of the silicon-based substrate using photolithographic techniques with precision controlled at micro-scales and/or nano-scales. Specifically, thin film deposition is performed on silicon substrate surface to obtain desired wetting properties. Embodiments may be applied to electronics and semiconductors applications where silicon wafers are used for the fabrication of integrated circuits and photovoltaic solar cells. Embodiments may also be applied to electronics and semiconductors applications where semiconductors or other electronic components are installed on fiber glass printed circuit boards to produce electronic device assemblies in various electronic products. In one or more embodiments, hydrophobic surfaces and hydrophilic channels are formed in selected regions of the fiber glass printed circuit board. For example, hydrophobic and hydrophilic materials may be printed on, painted on, or otherwise applied on the printed circuit board in a selective manner to form the drainage channels.

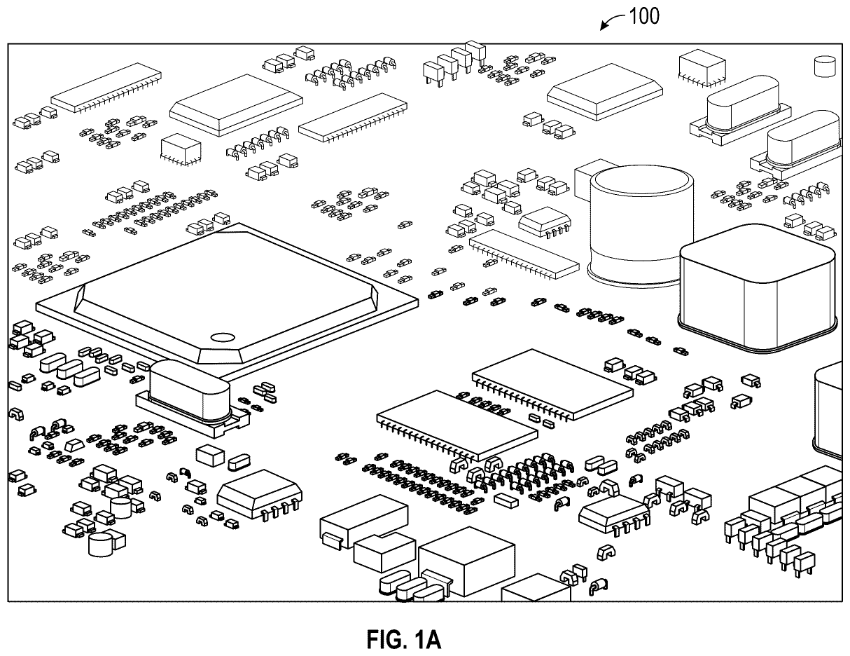

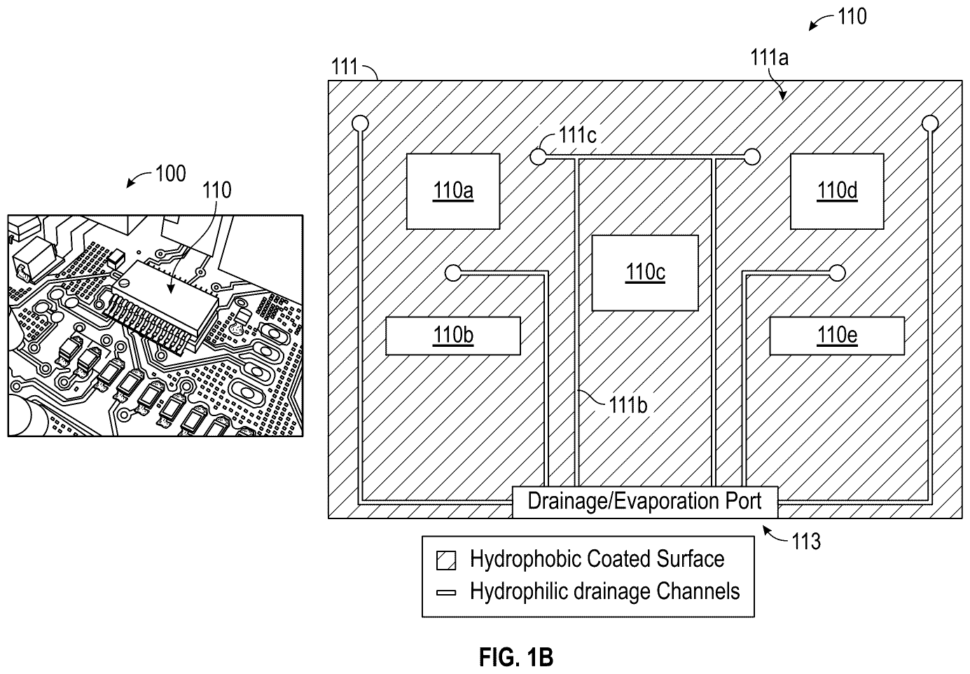

FIG. 1A shows a circuit board (100) containing silicon-based circuit modules with improved drainage in accordance with one or more embodiments. For example, the circuit board (100) may be a motherboard of a computer system where one or more electronic devices mounted on the motherboard contains a silicon-based circuit module with improved drainage. In another example, the circuit board (100) may be a motherboard of a computer system where the fiber glass printed circuit board itself includes improved drainage. In one or more embodiments, the improved drainage is based on drainage channels formed on a substrate with mixed wettability surfaces that are not explicitly shown in FIG. 1A. The substrate may be a silicon-based substrate or other types of substrate such as the fiber glass printed circuit board. Although not explicitly shown, other controller devices are also connected externally to motherboard, such as mouse, keyboard, digital versatile disc (DVD) and hard drive.

FIG. 1B shows a silicon-based circuit module (110) with improved drainage in accordance with one or more embodiments. As shown in FIG. 1B, the silicon-based circuit module (110) corresponds to an electronic device on the circuit board (100) depicted in FIG. 1 above. Specifically, the silicon-based circuit module (110) includes electronic circuitries (110a, 110b, 110c, 110d, 110e) fabricated on a silicon-based substrate (111). For example, the electronic circuitries (110a, 110b, 110c, 110d, 110e) may include read-only memory (ROM), central processing unit (CPU), random-access memory (RAM), peripheral component interconnect (PCI) slots, universal serial bus (USB) ports, and other electronic parts. In one or more embodiments, the silicon-based substrate (111) includes a designated hydrophobic region (111a) and a designated hydrophilic region (111b), shown as the hydrophobic coated surface and the hydrophilic drainage channels according to the legend (150). Further, multiple drainage channels originate from respective origins (111c) to terminate at a drainage/evaporation port (113). Each origin (111c) is a localized hydrophilic area for capturing moisture/fluid trapped in a surrounding area, such as a surrounding hydrophobic coated surface. Each drainage channel is a depressed hydrophilic groove cut into the silicon-based substrate for guiding the moisture/fluid flow away from the corresponding origin (111c). The drainage/evaporation port (113) is a localized hydrophilic area in a well-ventilated surrounding to allow moisture/fluid collected from the hydrophilic drainage channels to escape or otherwise be removed from the silicon-based circuit module (110). The drainage/evaporation port (113) may be disposed as part (e.g., an edge part) of the silicon-based substrate (111) or separate from the silicon-based substrate (111).

One main issue associated with reliability of electronic devices or computer systems, e.g., containing or based on the silicon-based circuit module (110), is their high sensitivity to moisture. Electronic parts may be damaged by water contact. Surface wettability or fluid affinity to substrate may vary dramatically depending on the type of substrate material and fluid. Accordingly, adjusting wetting properties of surface present an impact on water displacement, characterized by drainage or imbibition. Even with coating the electronic parts with hydrophobic material to repel fluids/water, any water droplet that enters the electronic device or computer system can be trapped and still cause damage to interior electronic parts. As illustrated above, wetting surfaces are selectively created in the designated hydrophilic region (111b) of the silicon-based substrate (111) to act as water drainage channels. In one or more embodiments, by tuning the wetting states of these channels, these channels become more hydrophilic while maintaining the remaining surface hydrophobic in the designated hydrophobic region (111a). Any water droplet, referred to as wetting-phase, touching those hydrophilic channels network will be drawn into the drainage/evaporation port (113) and escape or be removed from the silicon-based circuit module (110). Mechanism of water removal is based on capillary imbibition (or absorption) by the action of capillary forces.

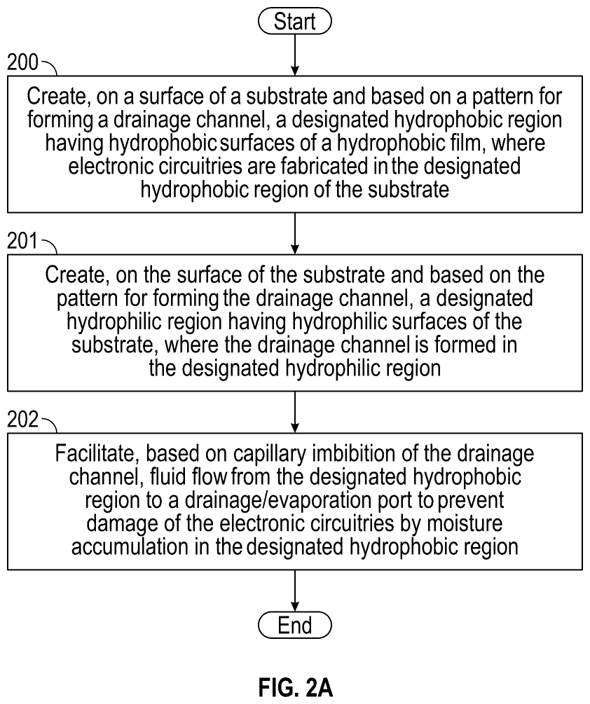

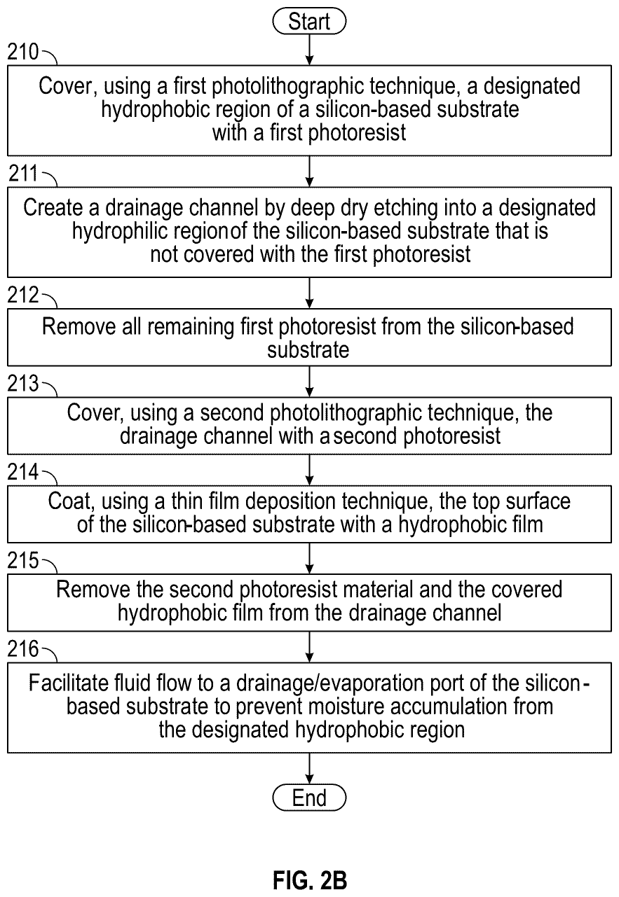

To create a fully hydrophobic coated surface, any stable hydrophobic coating may be used using physical or chemical deposition techniques. In one or more embodiments, Perfluorodecyltrichlorosilane (FDTS) material may be used as a hydrophobic coating using a thin film deposition procedure, such as atomic layer deposition (ALD), molecular vapor deposition (MVD), pulsed laser deposition (PLD), physical vapor deposition (PVD), chemical vapor deposition (CVD), sputtering, or evaporation, etc. Selective deposition of hydrophobic FDTS is achieved using a selective wettability control mask. The FDTS-coated regions of the surface shift the localized wetting state of the silicon towards hydrophobic, while wettability of un-coated silicon substrate remains unchanged. In one or more embodiments, the electronic circuitries (110a, 110b, 110c, 110d, 110e) are fabricated on the silicon-based substrate (111) throughout the designated hydrophobic region (111a) prior to fabricating the hydrophobic coated surface and the hydrophilic drainage channels of the silicon-based substrate (111). In one or more embodiments, the hydrophobic coated surface and the hydrophilic drainage channels depicted in FIG. 1B are fabricated using the method described in reference to FIG. 2 below.

Although the description above relates to the embodiments based on the silicon-based substrate and specific drainage channels formed on the silicon-based substrate, one skilled in the art will appreciate that alternative fabrication techniques may be employed to form drainage channels on other types of substrate, such as the fiber glass printed circuit board. As noted above, hydrophobic and hydrophilic materials may be printed on, painted on, or otherwise applied on the printed circuit board in a selective manner to form the drainage channels.

FIG. 2A shows a flowchart of a method in accordance with one or more embodiments disclosed herein. The method is used for fabricating a mixed wettability surface for water drainage of a substrate. In one or more embodiments, one or more of the steps shown in FIG. 2A may be omitted, repeated, and/or performed in a different order than the order shown in FIG. 2A. Accordingly, the scope of the disclosure should not be considered limited to the specific arrangement of steps shown in FIG. 2A.

Initially, in Step 200, a designated hydrophobic region is created that has hydrophobic surfaces of a hydrophobic film. In one or more embodiments, the designated hydrophobic region is created by selectively coating (e.g., printing, painting, depositing, or otherwise applying) hydrophobic material to form a patterned film on the substrate. For example, the patterned film may be defined by a pattern on a screen or a mask used in the printing, painting, depositing, or other application procedure. In particular, the pattern is determined for forming the drainage channel. In some embodiments, electronic circuitries are fabricated in the designated hydrophobic region of the substrate.

In Step 201, a designated hydrophilic region is created that has hydrophilic surfaces of the substrate. In one or more embodiments, the designated hydrophilic region corresponds to the remaining uncoated areas that are not covered by the hydrophobic patterned film. In one or more embodiments, a drainage channel is formed in the designated hydrophilic region.

In Step 202, fluid flow is facilitated from the designated hydrophobic region via the drainage channel to a drainage/evaporation port to prevent damage of the electronic circuitries by moisture accumulation in the designated hydrophobic region. In one or more embodiments, fluid flow from the designated hydrophobic region toward the drainage/evaporation port is facilitated based on capillary imbibition of the drainage channel.

FIG. 2B shows a flowchart of a method in accordance with one or more embodiments disclosed herein. The method is used for fabricating a mixed wettability surface for water drainage of a silicon-based substrate. In one or more embodiments, one or more of the steps shown in FIG. 2B may be omitted, repeated, and/or performed in a different order than the order shown in FIG. 2B. Accordingly, the scope of the disclosure should not be considered limited to the specific arrangement of steps shown in FIG. 2B.

In one or more embodiments, the fabrication method includes photolithography and thin-film deposition. The photolithography is a process of transferring pattern from a mask to a photoresist layer on top of a substrate. The thin-film deposition is a process to place a very thin layer of material on top of the substrate surface.

Initially, in Step 210, a designated hydrophobic region of the silicon-based substrate is covered with a first photoresist using a first photolithographic technique. Separate from the designated hydrophobic region, a designated hydrophilic region of the silicon-based substrate is not covered with the first photoresist.

In one or more embodiments, the designated hydrophobic region of the silicon-based substrate is covered with the first photoresist by performing the following sub-steps 200a through 200e using the first photolithographic technique.

In a first sub-step 210a, the top surface of the silicon-based substrate is covered with the first photoresist, e.g., by a spinning method.

In a second sub-step 210b, the top of the first photoresist is covered with a photomask having a pattern transparent to UV light. The pattern delineates the designated hydrophobic region and the designated hydrophilic region. In particular, the designated hydrophilic region corresponds to the pattern of intended drainage channels. In this context, the photomask is referred to as a wettability control mask. In the case where the first photoresist is a positive photoresist, the transparent pattern of the photomask defines the designated hydrophilic region. In the opposite case where the first photoresist is a negative photoresist, the transparent pattern of the photomask defines the designated hydrophobic region.

In a third sub-step 210c, the covered top of the first photoresist is exposed to UV light that selectively changes a first chemical property of the first photoresist according to the transparent pattern of the photomask. In the case where the first photoresist is a positive photoresist, the exposed first photoresist under the transparent pattern of the photomask becomes degraded and soluble to a photoresist developer while the unexposed first photoresist remains undegraded and insoluble to a photoresist developer. In the opposite case where the first photoresist is a negative photoresist, the exposed first photoresist under the transparent pattern of the photomask becomes strengthened and insoluble to a photoresist developer while the unexposed first photoresist remains un-strengthened and soluble to a photoresist developer.

In a fourth sub-step 210d, the photomask is removed to apply the photoresist developer to the silicon-based substrate coated with the first photoresist.

In a fifth sub-step 210e, the degraded or un-strengthened first photoresist is removed across the designated hydrophilic region based on the changed first chemical property of the first photoresist. In contrast, the remaining designated hydrophobic region remains covered with the first photoresist.

In Step 211, a drainage channel is created by deep dry etching into the designated hydrophilic region of the silicon-based substrate that is not covered with the first photoresist.

In Step 212, all remaining first photoresist is removed from the silicon-based substrate using a lift-off solvent, such as N-methyl pyrrolidone (NMP).

In Step 213, the drainage channel is covered with a second photoresist using a second photolithographic technique. Separate from the drainage channel in the designated hydrophilic region, the designated hydrophobic region of the silicon-based substrate is not covered with the second photoresist.

In one or more embodiments, the drainage channel is covered with the second photoresist by performing the following sub-steps 203a through 203e using the second photolithographic technique.

In a first sub-step 213a, the top surface of the silicon-based substrate is covered with the second photoresist, e.g., by a spinning method.

In a second sub-step 213b, the top of the second photoresist is covered with the photomask that is aligned to the drainage channel. In the case where the first photoresist and the second photoresist have the opposite polarities (i.e., one is positive and the other one is negative), the same version of photomask is used for both the first photolithographic technique and the second photolithographic technique. In the opposite case where the first photoresist and the second photoresist have the same polarities (i.e., both being positive or both being negative), inverse versions of photomask are used for the first photolithographic technique and the second photolithographic technique. Specifically, the transparent pattern in the photomask for the first photolithographic technique becomes the non-transparent pattern in the photomask for the second photolithographic technique.

In a third sub-step 213c, the covered top of the first photoresist is exposed to UV light that selectively changes a second chemical property of the second photoresist according to the transparent pattern of the photomask.

In a fourth sub-step 213d, the photomask is removed to apply the photoresist developer to the silicon-based substrate coated with the second photoresist.

In a fifth sub-step 213e, the degraded or un-strengthened second photoresist is removed across the designated hydrophobic region based on the changed second chemical property of the second photoresist. In contrast, the drainage channel in the designated hydrophilic region remains covered with the second photoresist.

In Step 214, the top surface of the silicon-based substrate is coated with a hydrophobic film using a thin film deposition technique. For example, the hydrophobic film may include Perfluorodecyltrichlorosilane (FDTS) material. In one or more embodiments, the thin film deposition technique includes atomic layer deposition (ALD), molecular vapor deposition (MVD), pulsed laser deposition (PLD), physical vapor deposition (PVD), chemical vapor deposition (CVD), sputtering, or evaporation, or other suitable deposition technique.

In Step 215, the second photoresist material is removed from the drainage channel using the lift-off solvent, such as N-methyl pyrrolidone (NMP). In response to removing the second photoresist material, the hydrophobic film is removed along with the second photoresist material from the drainage channel. Accordingly, the designated hydrophobic region of silicon-based substrate now includes hydrophobic surfaces of remaining hydrophobic film, while the drainage channel includes hydrophilic surfaces of the silicon-based substrate. to facilitate fluid flow to a drainage/evaporation port external to the silicon-based substrate, and

In Step 216, fluid flow is facilitated by the drainage channel to a drainage/evaporation port of the silicon-based substrate to prevent moisture accumulation from the designated hydrophobic region.

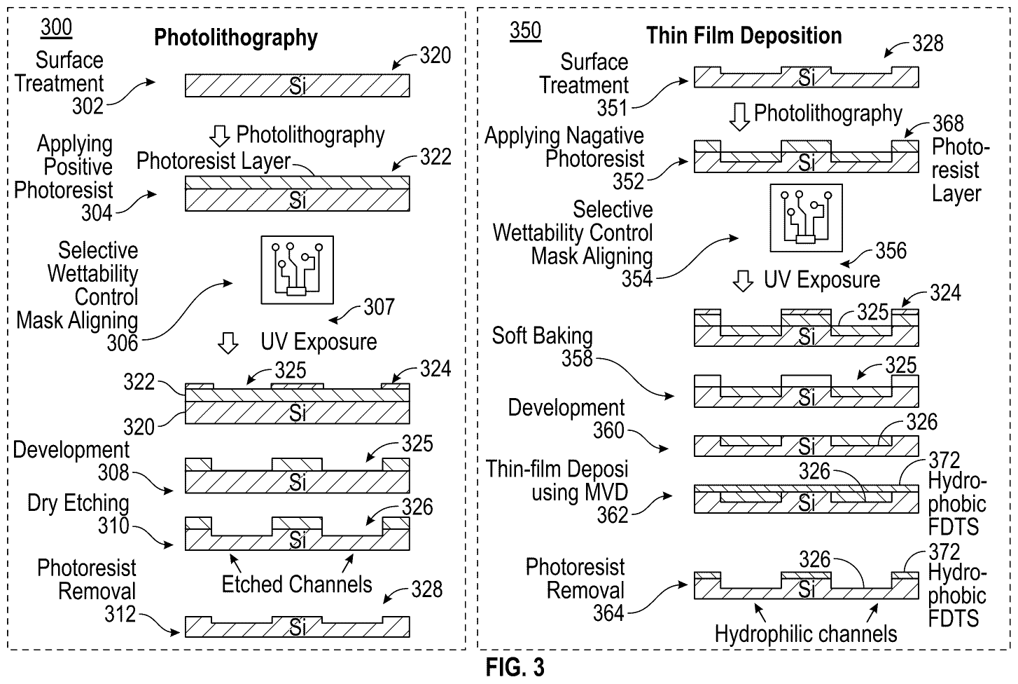

FIG. 3 shows a schematic diagram depicting a silicon-based substrate undergoing fabrication using photolithographic techniques in accordance with one or more embodiments. In particular, the schematic diagram includes a first section (300) referred to as “Photolithography” and a second section (350) referred to as “Thin-film Deposition.” In one or more embodiments, one or more of the steps shown in FIG. 3 may be omitted, repeated, and/or performed in a different order than the order shown in FIG. 3. Accordingly, the scope of the disclosure should not be considered limited to the specific arrangement of steps shown in FIG. 3.

In the first section (300) shown in FIG. 3 a photolithography process is performed to transfer a pattern (325) from a wettability control mask (324) to the silicon-based substrate (320) and to create drainage channels (326) according to the transferred patterns (325). The first section (300) includes the following steps.

In Step 302, initial surface pretreatments are applied to the silicon-based substrate (320), which include: (1) dehydration of the silicon-based substrate (320) by baking at high temperature (150° C.) to remove any moisture on the wafer surface; (2) surface treatment with adhesion promoter to facilitate adhesion of the photoresist (322) to the substrate surface; and (3) oxygen plasma may be used before applying the adhesion promoter for surface activation.

In Step 304, photoresist (322) is applied on the top surface of the treated substrate (320). In the scenario illustrated in FIG. 3, positive photoresist is used in this step. In other scenarios, negative photoresist may also be used. Soft baking of the substrate (320) is performed using a hot plate to remove any volatile solvents in the photoresist (322) after coating.

In Step 306, the wettability control mask (324) is aligned with the photoresist coated substrate (324).

In Step 307, UV exposure is performed using the partially transparent wettability control mask (324) that allows UV light to shine through a transparent pattern (325) of the wettability control mask (324). The transparent pattern (325) defines a designated hydrophilic region of the silicon-based substrate (320) where drainage channels (326) are created. In this context, the pattern (325) is also referred to as the channel pattern. The exposure to intense UV light “prints” the channel pattern (325) of the wettability control mask (324) onto the photoresist (322). The term “print” refers to changing a chemical property (i.e., solubility in a photoresist developer) of the photoresist (322). Using the positive photoresist (322), a portion of the photoresist (322) covering the transparent pattern (325) becomes soluble to the positive photoresist developer after the UV exposure. Feature size of the printed pattern may be as fine as 1 μm.

In Step 308, development process is performed to remove soluble photoresist material after UV exposure. The development is based on photoresist material type (referred to as polarity such as positive type or negative type) that are used. Since positive photoresist is used, the exposed areas of the photoresist corresponding to the channel pattern (325) become soluble (degraded by UV light) to the photoresist developer. The unexposed areas (covered under non-transparent portions of the mask) of the photoresist remains insoluble to the photoresist developer.

In Step 310, deep dry etching is performed to etch away substrate material uncovered with the remaining photoresist to create the drainage channels (326) in the substrate. Etched drainage channels (326) are created by engraving the silicon substrate (320) into a patterned silicon-based substrate (328).

In Step 312, the remaining photoresist is removed from silicon surface using a lift-off solvent, such as N-methyl pyrrolidone (NMP). Piranha solution, a mixture of sulfuric acid and hydrogen peroxide, may be used for further cleaning of the patterned silicon-based substrate (328).

In the second section (350) shown in FIG. 3B, the patterned silicon-based substrate (328) created by photolithography is coated to establish the desired wetting conditions of the surface. The thin-film deposition technique used in the workflow includes molecular vapor deposition (MVD) or any other physical vapor deposition (PVD) or chemical vapor deposition (CVD) techniques. The second section (350) includes the following steps.

In Step 351, initial surface pretreatments are applied to the patterned silicon-based substrate (328), which include: (1) dehydration of the patterned silicon-based substrate (328) by baking at high temperature (150° C.) to remove any moisture on the wafer surface; (2) surface treatment with adhesion promoter to facilitate adhesion of the photoresist (322) to the substrate surface; and (3) oxygen plasma may be used before applying the adhesion promoter for surface activation.

In Step 352, photoresist (368) is applied on the top of the patterned silicon-based substrate (328). In the scenario illustrated in FIG. 3, negative photoresist is used in this step. In other scenarios, positive photoresist may also be used. The coated substrate is soft baked on a hot plate to remove any volatile solvents in the photoresist after coating.

In Step 354, a photomask is aligned with the channel pattern (325) previously engraved in the photoresist coated patterned silicon-based substrate (328). In one or more embodiments, the wettability control mask (324) used in Step 306 above is used as the photomask in this step.

In Step 356, UV exposure is performed using the same wettability control mask (324) used to transfer the channel pattern (325), After the UV exposure, the portion of the negative photoresist covering the channel pattern (325) becomes strengthened and insoluble to the negative photoresist developer.

In Step 358, the photoresist coated patterned silicon substrate (328) is soft baked after UV exposure at 110° C. for one minute.

In Step 360, development process is performed to remove photoresist material after the UV exposure. Development is based on the type of photoresist material used. Since negative photoresist is used in this step, the exposed areas of the photoresist corresponding to the channel pattern (325) become insoluble to the photoresist developer. On the other hand, the unexposed areas of the negative photoresist is dissolved by the photoresist developer to expose the underlying surface of the silicon-based substrate (320).

In Step 362, the surface of the photoresist coated patterned silicon-based substrate (328) is coated with FDTS (372) using MVD or other suitable techniques to create a hydrophobic coating. A very thin layer is deposited with few nanometers thickness.

In Step 364, the remaining photoresist covering the etched drainage channels (326) is removed using a lift-off process. The thin layer of FDTS (372) covering the etched drainage channels (326) is lifted off along with the photoresist to restore the original substrate surface in the area of the etched channels (326). This is done using a lift-off solvent, such as N-methyl pyrrolidone NMP. Accordingly, the drainage channels (326) now has hydrophilic surface of the silicon-based substrate (320) while the remaining surface covered with FDTS (372) are hydrophobic.

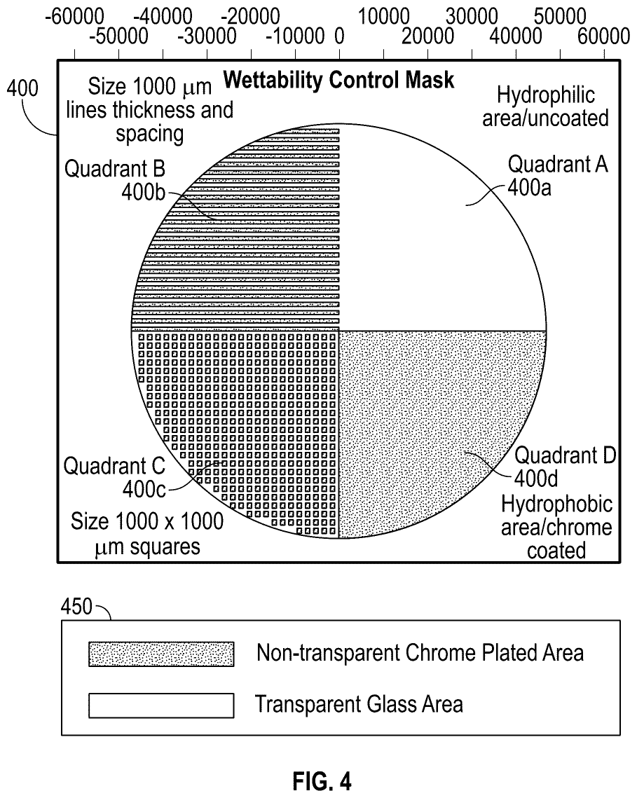

FIG. 4 shows an example wettability control mask (400) in accordance with one or more embodiments. The example wettability control mask (400) includes a test pattern defining selective hydrophobic and hydrophilic regions and is used only for the purpose of validating the fabrication workflow described in reference to FIGS. 2 and 3 above. The wettability control mask (400) is divided into four quarters where the test pattern includes non-transparent chrome plated areas and transparent glass areas depicted according to the legend (450). When the example wettability control mask (400) is used as the wettability control mask (324) depicted in FIG. 3 above, the non-transparent chrome plated areas correspond to the designated hydrophobic region and the transparent glass areas correspond to the designated hydrophilic region. As shown in FIG. 4, quadrant A (400a) of the test pattern is used to create a completely hydrophilic region on the silicon-based substrate, quadrant B (400b) of the test pattern is used to create alternating hydrophilic and hydrophobic lines (e.g., 1000 μm width) on the silicon-based substrate, quadrant C (400c) of the test pattern is used to create alternating hydrophilic and hydrophobic squares (e.g., 1000 μm in size), and quadrant D (400d) of the test pattern is used to create a completely hydrophobic region on the silicon-based substrate.

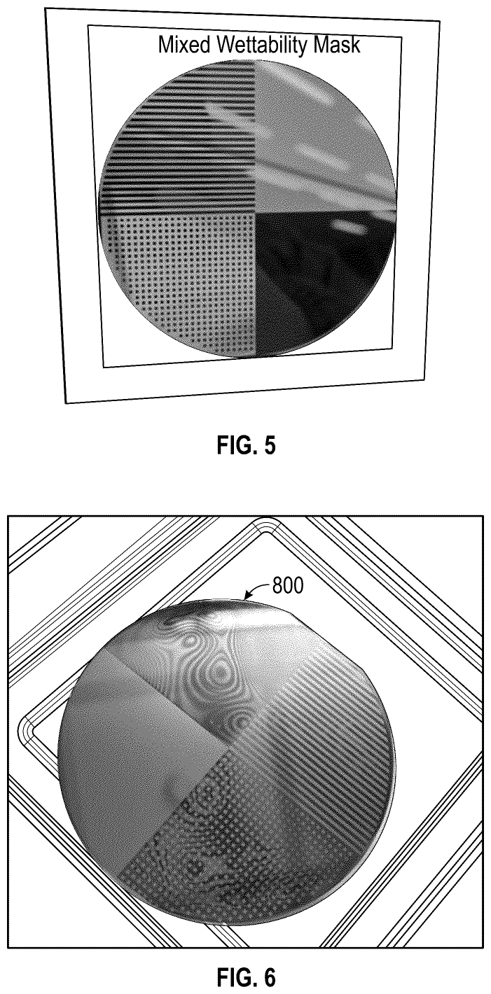

FIG. 5 shows a photograph of a fabricated wettability control mask having the test pattern depicted in FIG. 4 above.

FIG. 6 shows a photograph of a silicon wafer (800) fully coated with FDTS on top of photoresist after transferring the test pattern from the fabricated wettability control mask depicted in FIG. 5 above. For example, the photograph may correspond to the step 362 depicted in FIG. 3 above.

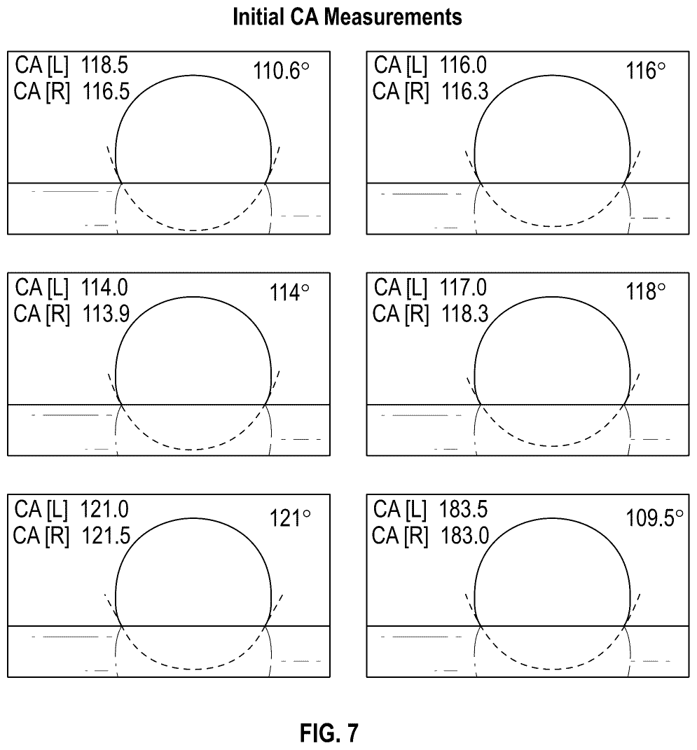

FIG. 7 shows magnified images of deionized water droplets on the surface of the patterned silicon wafer coated with FDTS as depicted in FIG. 6 above. The high contact angles obtained from multiple measurements range from 109.5⁰ to 121⁰. This confirms the initial hydrophobicity of the FDTS coated silicon wafer prior to the lift-off process.

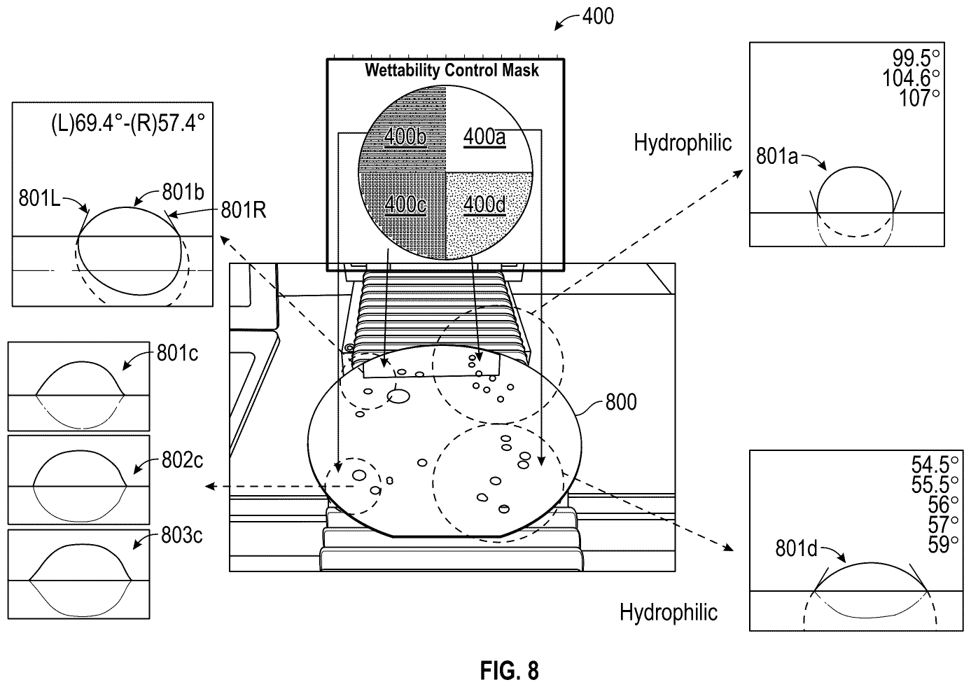

FIG. 8 shows a photograph of the FDTS coated and patterned silicon wafer (800) depicted in FIG. 7 above but after the lift-off process to create the designated hydrophilic region. As noted above, test patterns in the four quadrants (400a, 400b, 400c, 400d) of the wettability control mask (400) are transferred onto four corresponding quadrants of the FDTS coated and patterned silicon wafer (800). As shown in FIG. 8, contact angle measurements of deionized water droplets (801a, 801b, 801c, 802c, 803c, 801d) in the four quadrants of the FDTS coated and patterned silicon wafer (800) confirms that areas covered with FDTS are hydrophobic while the areas without FDTS deposited are hydrophilic. For example, the water/air contact angle of deionized water droplets (801a) in the completely hydrophobic region ranges between 99°-107° while the water/air contact angle of deionized water droplets (801d) in the completely hydrophilic region ranges between 54°-59°. Further, the water/air contact angle of deionized water droplets (801b) in the alternating hydrophilic and hydrophobic lines area exhibits hysteresis between left side contact angle (801L) and right side contact angles (801R), measured as 69.4° and 57.4⁰, respectively, which is referred to as alternating wettability. Similarly, the water/air contact angle of deionized water droplets (801c, 802c, 803c) in the alternating hydrophilic and hydrophobic squares area also exhibits hysteresis as well as irregular droplet shapes due to the alternating wettability.

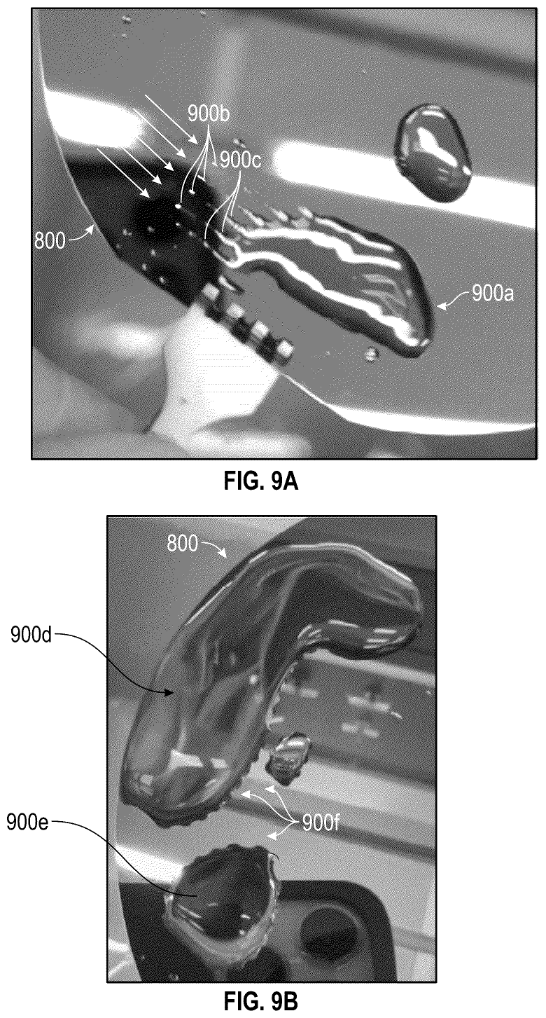

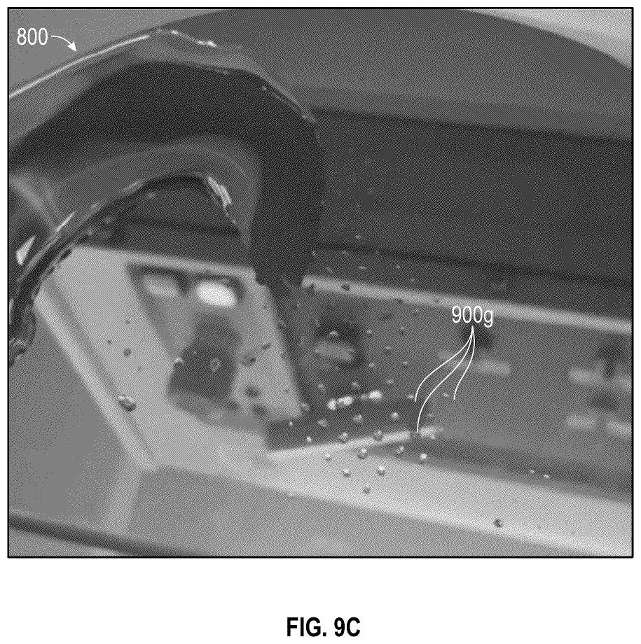

FIG. 9A shows a photograph of water flowing over the alternating hydrophobic/hydrophilic lines area of the FDTS coated and patterned silicon wafer (800) depicted in FIG. 8 above. Waterfront (900a) attempts to follow hydrophilic lines (900b) thus creating clear tails (900c) in the back phases while passing through drainage channels formed by the hydrophilic lines (900b).

FIG. 9B shows a photograph of water droplets (900d, 900e) trapped between hydrophobic lines over the alternating hydrophobic/hydrophilic lines area of the FDTS coated and patterned silicon wafer (800) depicted in FIG. 8 above. In particular, portions (900f) of the confined boundaries of the water droplets (900d, 900e) are modulated by nearest hydrophobic lines.

FIG. 9C shows a photograph of water droplets (900g) trapped at hydrophobic squares over the alternating hydrophobic/hydrophilic squares area of the FDTS coated and patterned silicon wafer (800) depicted in FIG. 8 above.

As illustrated above, embodiments allow wetting surfaces to be selectively created in the designated hydrophilic region of a silicon-based substrate of silicon-based circuit module to act as water drainage channels. In one or more embodiments, by tuning the wetting states of these channels, these channels become more hydrophilic while maintaining the remaining surface hydrophobic in the designated hydrophobic region. Any water droplet, referred to as wetting-phase, touching those hydrophilic channels network will be drawn into a drainage/evaporation port and escape or be removed from the silicon-based circuit module. Mechanism of water removal is based on capillary imbibition (or absorption) by the action of capillary forces in the hydrophilic drainage channels. It is further contemplated that the alternating hydrophilic and hydrophobic line/square patterns may be used to facilitate water/moisture flow along non-linear (e.g., at a turning angle) portions of the drainage channels based on the hysteresis or alternating wettability behaviors.

Embodiments disclosed herein are directly applicable for manufacturing in various industries, such as electronic, electrical, computer system, information technology (IT), telecom, devices manufacturing companies. Expected commercial applications include generation of mixed wettability surface which may be used in many fields of application such as environmental engineering, biomedical, and electronics.

Embodiments disclosed herein exhibit at least the following advantages: (i) providing a simple fabrication procedure, (ii) causing less chemistry interference and uncertainty in the fabrication outcomes, (iii) causing less complexity in term of pattern creation, (iv) generating clean surface, and (v) providing better protection for electronic parts from water or liquids.

While one or more embodiments have been described with respect to a limited number of embodiments, those skilled in the art, having benefit of this disclosure, will appreciate that other embodiments may be devised which do not depart from the scope as disclosed herein. Accordingly, the scope should be limited only by the attached claims.

What is claimed is:

1. A method for water drainage of a substrate, comprising:
creating, on a surface of the substrate, a designated hydrophobic region comprising hydrophobic surfaces of a hydrophobic film, wherein electronic circuitries are fabricated in the designated hydrophobic region of the substrate;
creating, on the surface of the substrate, a designated hydrophilic region comprising hydrophilic surfaces of the substrate, wherein a drainage channel is formed in the designated hydrophilic region; and
facilitating, based on capillary imbibition of the drainage channel, fluid flow from the designated hydrophobic region to a drainage/evaporation port to prevent damage of the electronic circuitries by moisture accumulation in the designated hydrophobic region,
wherein the designated hydrophobic region and the designated hydrophilic region are delineated based on a pattern for forming the drainage channel.

2. The method according to claim 1,
wherein the substrate comprises a printed circuit board, and
wherein the electronic circuitries comprise at least one electronic integrated circuit device.

3. The method according to claim 1,
wherein the substrate comprises a silicon-based substrate, and
wherein the drainage channel is formed by at least:
covering, using a first photolithographic technique, the designated hydrophobic region of the silicon-based substrate with a first photoresist, wherein the designated hydrophilic region of the silicon-based substrate is not covered with the first photoresist;
creating the drainage channel by deep dry etching into the designated hydrophilic region of the silicon-based substrate that is not covered with the first photoresist;
removing all remaining first photoresist from the silicon-based substrate using a lift-off solvent;
covering, using a second photolithographic technique, the drainage channel with a second photoresist, wherein the designated hydrophobic region of the silicon-based substrate is not covered with the second photoresist;
coating, using a thin film deposition technique, the top surface of the silicon-based substrate with the hydrophobic film;
removing the second photoresist material from the drainage channel using the lift-off solvent; and
removing, in response to removing the second photoresist material, the hydrophobic film from the drainage channel,
wherein the designated hydrophobic region of silicon-based substrate comprises the hydrophobic surfaces of remaining hydrophobic film, and
wherein the drainage channel comprises the hydrophilic surfaces of the silicon-based substrate to facilitate fluid flow to a drainage/evaporation port of the silicon-based substrate.

4. The method according to claim 3, further comprising:
creating a silicon-based circuit module comprising the silicon-based substrate and the drainage/evaporation port.

5. The method according to claim 3,
wherein the hydrophobic film comprises Perfluorodecyltrichlorosilane (FDTS), and
wherein the lift-off solvent comprises N-methyl pyrrolidone (NMP).

6. The method according to claim 3, wherein the thin film deposition technique comprises one or more of atomic layer deposition (ALD), molecular vapor deposition (MVD), pulsed laser deposition (PLD), physical vapor deposition (PVD), chemical vapor deposition (CVD), sputtering, or evaporation.

7. The method according to claim 3, wherein said covering the designated hydrophobic region of the silicon-based substrate using the first photolithographic technique comprises:
coating a top surface of the silicon-based substrate with the first photoresist;
covering a top of the first photoresist with a photomask, wherein the photomask comprises the pattern transparent to UV light and delineating the designated hydrophobic region and the designated hydrophilic region;
exposing the covered top of the first photoresist to UV light that selectively changes a first chemical property of the first photoresist according to the transparent pattern of the photomask;
removing the photomask; and
removing the first photoresist across the designated hydrophilic region based on the changed first chemical property of the first photoresist, and
wherein the designated hydrophobic region remains covered with the first photoresist.

8. The method according to claim 7, wherein said covering the drainage channel using the second photolithographic technique comprises:
coating the top surface of the silicon-based substrate with a second photoresist;
covering the top of the second photoresist with the photomask, wherein the photomask is aligned to the drainage channel;
exposing the covered top of the second photoresist to UV light that selectively changes a second chemical property of the second photoresist according to the transparent pattern of the photomask;
removing the photomask; and
removing the second photoresist across the designated hydrophobic region based on the changed second chemical property of the second photoresist, and
wherein the drainage channel remains covered with the second photoresist.

9. The method according to claim 8, wherein the first photoresist and the second photoresist are removed by applying respective photoresist developers.

10. The method according to claim 9,
wherein at least one of the first photoresist and the second photoresist is a positive photoresist,
wherein a first region of the positive photoresist exposed to UV light is degraded and becomes soluble to a positive photoresist developer, and
wherein a second region of the positive photoresist covered by the photomask from UV light remains undegraded and insoluble to the positive photoresist developer.

11. The method according to claim 9,
wherein at least one of the first photoresist and the second photoresist is a negative photoresist,
wherein a first region of the negative photoresist exposed to UV light is strengthened and becomes insoluble to a negative photoresist developer, and
wherein a second region of the negative photoresist covered by the photomask from UV light remains un-strengthened and soluble to the negative photoresist developer.

12. A substrate with improved water drainage, comprising:
a designated hydrophobic region comprising hydrophobic surfaces of a hydrophobic film, wherein electronic circuitries are fabricated in the designated hydrophobic region of the substrate; and
a designated hydrophilic region comprising hydrophilic surfaces of the substrate, wherein a drainage channel is formed in the designated hydrophilic region,
wherein the drainage channel facilitates fluid flow from the designated hydrophobic region to a drainage/evaporation port of the silicon-based substrate to prevent damage of the electronic circuitries by moisture accumulation in the designated hydrophobic region, and
wherein the designated hydrophobic region and the designated hydrophilic region are delineated based on a pattern for forming the drainage channel.

13. The substrate according to claim 12,
wherein the substrate comprises a silicon-based substrate, and
wherein the electronic circuitries comprise at least one electronic integrated circuit device.

14. The substrate according to claim 12,
wherein the substrate comprises a silicon-based substrate, and
wherein the drainage channel is formed by at least:
covering, using a first photolithographic technique, the designated hydrophobic region of the silicon-based substrate with a first photoresist, wherein the designated hydrophilic region of the silicon-based substrate is not covered with the first photoresist;
deep dry etching into the designated hydrophilic region of the silicon-based substrate to form the drainage channel;
removing all remaining first photoresist from the silicon-based substrate using a lift-off solvent;
covering, using a second photolithographic technique, the drainage channel with a second photoresist, wherein the designated hydrophobic region of the silicon-based substrate is not covered with the second photoresist;
coating, using a thin film deposition technique, the top surface of the silicon-based substrate with a hydrophobic film;
removing the second photoresist material from the drainage channel using the lift-off solvent; and
removing, in response to removing the second photoresist material, the hydrophobic film from the drainage channel.

15. The substrate according to claim 14, wherein said covering the designated hydrophobic region of the silicon-based substrate using the first photolithographic technique comprises:
coating a top surface of the silicon-based substrate with the first photoresist;
covering a top of the first photoresist with a photomask, wherein the photomask comprises the pattern transparent to UV light and delineating the designated hydrophobic region and the designated hydrophilic region;
exposing the covered top of the first photoresist to UV light that selectively changes a first chemical property of the first photoresist according to the transparent pattern of the photomask;
removing the photomask; and
removing the first photoresist across the designated hydrophilic region based on the changed first chemical property of the first photoresist, and
wherein the designated hydrophobic region remains covered with the first photoresist.

16. The substrate according to claim 15, wherein said covering the drainage channel using the second photolithographic technique comprises:
coating the top surface of the silicon-based substrate with a second photoresist;
covering the top of the second photoresist with the photomask, wherein the photomask is aligned to the drainage channel;
exposing the covered top of the second photoresist to UV light that selectively changes a second chemical property of the second photoresist according to the transparent pattern of the photomask;
removing the photomask; and
removing the second photoresist across the designated hydrophobic region based on the changed second chemical property of the second photoresist, and
wherein the drainage channel remains covered with the second photoresist.

17. A circuit module with improved water drainage, comprising:
a substrate comprising:
a designated hydrophobic region comprising hydrophobic surfaces of a hydrophobic film; and
a designated hydrophilic region comprising hydrophilic surfaces of the substrate, wherein a drainage channel is formed in the designated hydrophilic region,
wherein the designated hydrophobic region and the designated hydrophilic region are delineated based on a pattern for forming the drainage channel;
a drainage/evaporation port of the substrate; and
electronic circuitries fabricated in the designated hydrophobic region of the substrate,
wherein the drainage channel facilitates fluid flow from the designated hydrophobic region to a drainage/evaporation port of the silicon-based substrate to prevent damage of the electronic circuitries by moisture accumulation in the designated hydrophobic region.

18. The circuit module according to claim 17, wherein the substrate comprises a printed circuit board.

19. The circuit module according to claim 17,
wherein the substrate comprises a silicon-based substrate, and
wherein the drainage channel is formed by at least:
covering, using a first photolithographic technique, the designated hydrophobic region of the silicon-based substrate with a first photoresist, wherein the designated hydrophilic region of the silicon-based substrate is not covered with the first photoresist;
deep dry etching into the designated hydrophilic region of the silicon-based substrate to form the drainage channel;
removing all remaining first photoresist from the silicon-based substrate using a lift-off solvent;
covering, using a second photolithographic technique, the drainage channel with a second photoresist, wherein the designated hydrophobic region of the silicon-based substrate is not covered with the second photoresist;
coating, using a thin film deposition technique, the top surface of the silicon-based substrate with a hydrophobic film;
removing the second photoresist material from the drainage channel using the lift-off solvent; and
removing, in response to removing the second photoresist material, the hydrophobic film from the drainage channel.

20. The circuit module according to claim 19, wherein the hydrophobic film comprises Perfluorodecyltrichlorosilane (FDTS).
